(19) United States
(12) Patent Application Publication
(10) Pub. No.: US 2017/0345960 A1
(43) Pub. Date: Nov. 30, 2017

(54) SOLAR CELL MODULE AND METHOD OF MANUFACTURE THEREOF

(71) Applicant: Panasonic Intellectual Property Management Co., Ltd., Osaka (JP)

(72) Inventors: KEI TOYOTA, Osaka (JP); NAOMICHI OHASHI, Hyogo (JP)

(21) Appl. No.: 15/485,831

(22) Filed: Apr. 12, 2017

(30) Foreign Application Priority Data
May 27, 2016 (JP) 2016-106537

(51) Int. Cl. H01L 31/055; C09K 11/02; C09K 11/59; H01L 31/048

(52) U.S. Cl. CPC H01L 31/055; H01L 31/048; C09K 11/025; C09K 11/595

(57) ABSTRACT

Provided herein is a solar cell module with which high output can be achieved through wavelength conversion of shorter wavelength light to longer wavelength light while extending life by removing ultraviolet light. A method of manufacture of the solar cell module is also provided. The solar cell module includes a back sheet, a first sealing material layer, a plurality of photoelectric conversion devices that are electrically connected to one another by an electrode material, a second sealing material layer, and a protective glass that are laminated in this order. The second sealing material layer is configured from a first layer, a second layer, and a third layer. The first layer is disposed in contact with the protective glass, and formed of a transparent material containing a phosphor. The third layer is disposed in contact with the photoelectric conversion, devices, and formed of a transparent material containing an ultraviolet absorber. The second layer is a transparent material disposed between the first layer and the third layer.

### TECHNICAL FIELD

The technical field relates to a solar cell module, and to a method of manufacture thereof.

### BACKGROUND

Solar cell modules typically have low sensitivity characteristics In shorter wavelength regions, and fail to make effective use of light of shorter wavelengths, including the ultraviolet light in sunlight. A phosphor, a substance that absorbs light of shorter wavelength regions, and fluoresces light of longer wavelength regions, has been used as a wavelength conversion material in an attempt to increase the quantity of longer wavelength light of higher sensitivity characteristics, and to improve the output of a solar cell module. For example, JP-A-57-28149, and JP-A-57-189 describe polymers obtained by dissolving organic phosphors in a polyacrylate-based transparent resin, and propose use of such polymers as a molded article capable of efficiently converting shorter wavelength light to longer wavelength light, and having desirable weather resistance. WO2008/047427 proposes improving solar cell module efficiency by mixing a rare-earth phosphor into an ethylene-vinyl acetate copolymer used as a protective resin for a photoelectric conversion device.

### SUMMARY

The photoelectric conversion device of a solar cell module deteriorates after prolonged exposure to ultraviolet (UV) light, and the UV component needs to be removed from, light that falls on the photoelectric conversion device. For this purpose, a UV absorber is used in the front filler of the photoelectric conversion device. However, when the UV absorber is used with phosphors, the quantity of the UV light absorbed by the phosphors decreases, and the fluorescence becomes insufficient to improve efficiency. With phosphors alone, only limited quantities of UV light are absorbed, and HV light causes damage to the photoelectric conversion device over long use. This is an obstacle for extending solar cell life.

The present disclosure is intended to find a solution to the foregoing problems, and it is an object of the present disclosure to provide a solar sell module with which high output can be achieved through wavelength conversion of shorter wavelength light to longer wavelength light while extending life by removing ultraviolet light. A method of manufacture of the solar cell module is also provided.

An aspect of the present disclosure is a solar cell module that includes a back sheet, a first sealing material layer, a plurality of photoelectric conversion devices that are electrically connected to one another by an electrode material, a second sealing material layer, and a protective glass that are laminated in this order,

wherein the second sealing material layer is configured from a first layer, a second layer, and a third layer,

the first layer being disposed in contact with the protective glass and formed of a transparent material containing a phosphor,

the third layer being disposed in contact with the photoelectric conversion devices and formed of a transparent material containing an ultraviolet absorber,

the second layer being a transparent material disposed between the first layer and the third layer.

Another aspect of the present disclosure is a method for manufacturing the solar cell module. For example, the method includes:

forming the second sealing material layer of a three-layer structure in advance by laminating the first layer, the second layer, and the third layer;

electrically connecting the plurality of photoelectric conversion, devices to one another with an electrode material;

stacking the back sheet, the first sealing material layer that fills between the back sheet and the photoelectric conversion devices, the plurality of photoelectric conversion devices that are electrically connected to one another with the electrode material, the second sealing material layer of the three-layer structure, and the protective glass in this order; and

laminating the stacked members.

In the solar cell module according to the foregoing aspect of the disclosure, the second sealing material layer provided on the protective glass side of the photoelectric conversion, devices is configured from the first, layer, the second layer, and the third layer. The first layer is disposed in contact with the protective glass, and formed of a transparent material containing a phosphor. The third layer is disposed, in contact with the photoelectric conversion, devices, and formed of a transparent material containing a UV absorber. The second layer is a transparent material disposed between the first layer and the third layer. This configuration inhibits diffusion of phosphors from the first layer to the UV absorber-containing third layer, and diffusion of the UV absorber from the third layer to the phosphor-containing first layer. In this way, the high efficiency provided by wavelength conversion can remain for extended time periods in the product solar cell module.

The solar cell module manufacturing method according to the aspect of the present disclosure forms the second sealing material layer as a laminate in a lamination process that is performed beforehand. In this way, only laminates containing no bubbles or other unwanted substance can be selected as the second sealing material layer, and a low yield due to entry of bubbles can be prevented in the process of laminating the second sealing material layer to other members of the solar cell module.

### BRIEF DESCRIPTION OF THE DRAWINGS

FIG. 1 is a cross sectional view of a solar cell module of an embodiment of the present disclosure.

FIG. 2A is a cross sectional view representing manufacturing method A of the solar cell module of the embodiment of the present disclosure.

FIG. 2B is a cross sectional view representing manufacturing method A of the solar cell module of the embodiment of the present disclosure.

FIG. 3A is a cross sectional view representing manufacturing method B of the solar cell module of the embodiment of the present disclosure.

FIG. 3B is a cross sectional view representing manufacturing method B of the solar cell module of the embodiment of the present disclosure.

FIG. 4A is a cross sectional view representing manufacturing method C of the solar cell module of the embodiment of the present disclosure.

FIG. 4B is a cross sectional view representing manufacturing method C of the solar cell module of the embodiment of the present disclosure.

### DESCRIPTION OF EMBODIMENTS

A solar cell module of an embodiment of the present disclosure is described below in detail.

### Embodiment of the Present Disclosure

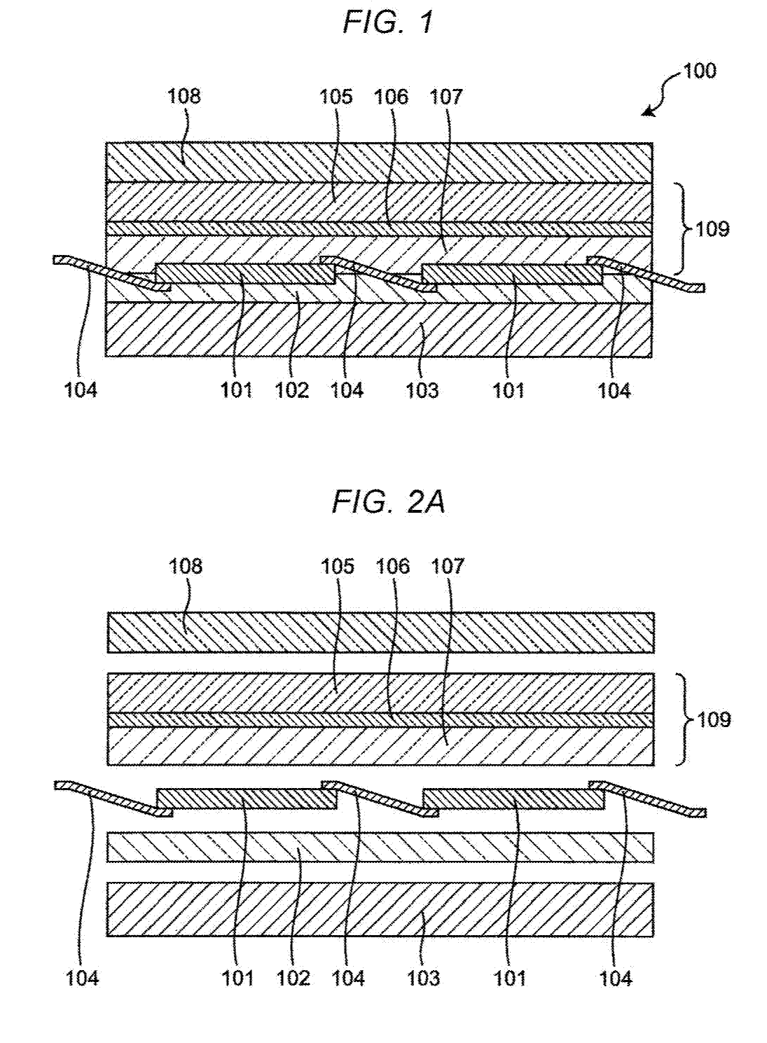

FIG. 1 is a cross sectional view showing a structure of a solar cell module 100 according to an embodiment of the present disclosure. The solar cell module 106 of the present embodiment is configured to include at least a back sheet 103, a first sealing material layer 102, photoelectric conversion devices 101 that are electrically connected to one another by electrodes 104, a second sealing material layer 109, and a protective glass 108, which are laminated in this order.

The first sealing material layer 102 is formed of a back transparent resin protecting the photoelectric conversion device 101.

The second sealing material layer 109 has a three-layer configuration with a first layer 105, a second layer 106, and a third layer 107. The first layer 105 is disposed in contact with the protective glass 108, and represents a transparent resin layer configured from a phosphor-containing transparent material, or, specifically, a phosphor layer 105. The second layer 106 is disposed between the first layer 105 and the third layer 107, and represents a barrier layer 106 configured from a transparent material. The third layer 107 is disposed in contact with the photoelectric conversion device 101, and represents a transparent resin layer configured from a UV absorber-containing transparent material, or, specifically, a UV absorber layer 107.

### Back Sheet

The back sheet 103 is provided to protect the photoelectric conversion devices 101 and the electrodes 104 from impact and moisture from the back of the solar cell module 100, and may be an insulating resin material. The resin material is not particularly limited, and may be, for example, a polyvinyl fluoride resin, a polyester resin, or a laminate of these resins.

### Photoelectric Conversion Device

The photoelectric conversion devices 101 are not particularly limited, and may be silicon semiconductors of, for example, monocrystalline silicon, polycrystalline silicon, or amorphous silicon, or may be compound semiconductors such as gallium-arsenic semiconductors, and cadmium-tellurium semiconductors.

The photoelectric conversion devices 101 are electrically joined to one another by the electrodes 104. The electrodes 104 say be known metallic materials or alloy materials.

### First Sealing Material Layer

The first sealing material layer 102 provided for protection on the back of the photoelectric conversion devices 101 is not particularly limited, and may be, for example, an ethylene-vinyl acetate copolymer, a bisphenol epoxy resin cured product, polyethylene, an acrylic resin, a silicone resin, or a polycarbonate resin.

### Protective Glass

The protective glass 108 is not particularly limited, and may be a known, translucent, impermeable plate-shape glass, transparent resin or other transparent protective materials.:

### Second Sealing Material Layer

The second sealing material layer 109 has a three-layer structure formed by the phosphor layer 105, the barrier layer 106, and the UV absorber layer 107. The second sealing material layer 109 is disposed on the light incident side of the photoelectric conversion devices 101. The second sealing material layer 109 is an important, essential member of the present embodiment, as described below in detail.

### Phosphor Layer

The phosphor layer 105 is a phosphor-containing transparent resin layer. The constituent transparent resin of the transparent resin, layer is not particularly limited, and may be, for example, polyvinyl chloride, polyvinylidene chloride, polyvinyl alcohol, polystyrene, a styrene-acrylonitrile copolymer, a styrene-butadiene-acrylonitrile copolymer, polyethylene, an ethylene-vinyl acetate copolymer, polypropylene, polymethyl methacrylate, a methacryl styrene polymer, cellulose acetate, a polycarbonate, a polyester, PET, trivinylidene fluoride, an epoxy resin, a silicone resin, polyether sulfone, a cycloolefin, or triacetate. These may be used alone or as a mixture of two or more.

The phosphor layer 105 may have a thickness of 100 μm to 1,000 μm though it depends on the phosphor content. A thickness thinner than 100 μm makes the absolute phosphor content smaller, and the effect of converting shorter wavelength light of low sensitivity characteristics to longer wavelength light, of high sensitivity characteristics becomes insufficient. When the thickness is thicker than 1,000 μm, the resin Itself absorbs light of the visible region, and this leads to poor conversion efficiency in the photoelectric conversion devices 101. The composition and: the type of the phosphor contained in the transparent, resin are not limited, and, for example, inorganic phosphors, organic phosphors, or inorganic-organic complex, phosphors may be appropriately used, either alone or in combination. From the perspective of improving output through absorption, of light of shorter wavelength regions for which the photoelectric conversion devices have poor sensitivity characteristics, and through fluorescence in longer wavelength regions of higher sensitivity characteristics, it is preferable in the embodiment of the present, disclosure that the phosphor layer 105 absorbs UV rays of 400 nm or shorter wavelengths, and fluoresces light of wavelengths longer than 400 nm.

When two different phosphors are used for the phosphor layer 105, it is preferable for improved output to choose phosphors so that the fluorescence wavelength of a first phosphor overlaps the absorption wavelength of a second phosphor because the phosphor layer 105 fluoresces light of wider wavelengths with such phosphors. For example, the phosphor may have a concentration, that makes the absorbance greater than 0.1 and less than 10 at the absorption peak wavelength of each phosphor, though the concentration depends on the absorption coefficient of the phosphor at each wavelength, or the thickness of the phosphor layer. A sufficient fluorescence quantity cannot be obtained when the absorbance is less than 0.1. When the absorbance is more than 10, the emission efficiency decreases as a result of concentration quenching due to absorption by the phosphor itself.

The inorganic phosphors are not particularly limited, and known materials may be used. Typically, for example, oxides, nitride, or sulfides with the activated metallic luminescent ions in the matrix, may be used. As an example of such inorganic phosphors, one or more elements such as B, Gd, O, S, Al, Ga, Ba, Sr, K, V, La, Cl, P, In, Zn, Y, Ca, and Mg are used, and one or more of elements, such as Sn, Ho, Tb, Nd, Ag, Mn, Ce, Eu, Dy, and Tm are activated as luminescent ions. When inorganic phosphors are used in the embodiment of the present disclosure, the grain size is desirably more than 30 nm and less than 300 nm.

When the grain size is 30 nm or less, the effect of surface defects of inorganic phosphors increases, and the emission efficiency drops. With a grain size of 300 nm or more, the light of wavelengths for which the photoelectric conversion devices have high sensitivity characteristics becomes lost as the light is scattered by inorganic phosphor particles.

The organic phosphors are not particularly limited, and, for example, hydrocarbon materials may foe used. Typically, hydrocarbons are represented by CₙH_{2n+2-2a-2b-4c}, where a is the number of rings contained in the structural formula, b is the number of carbon-carbon double bonds, and c is the number of carbon-carbon triple bonds. Usable as organic phosphors are hydrocarbons with 5<n<40 capable of fluorescence emission. Hydrocarbons with n≦5 do not usually function as phosphors that absorb ultraviolet light, and fluoresce light of wavelengths longer than 400 nm having high sensitivity characteristics. With n≧40, the absorption wavelength shifts toward the longer wavelength side, and light of high sensitivity characteristics becomes absorbed. This leads to poor output.

A part of the foregoing structural formula corresponding to carbon may be appropriately replaced by an oxygen atom, a nitrogen atom, or a sulfur atom, and whether the atom is ionized or not is not of concern. Preferred for chemical stability are, for example, fused-ring compounds such as anthracene, phenanthrene, pentacene, pyrene, perylene, benzpyrene, and coronene themselves, and derivatives thereof. Other specific examples of the organic phosphors include phosphors containing one or more of the following compounds: rhodamines, coumalin derivatives, quinacridone derivatives, benzooxazole derivatives, arylamine derivatives, distyrylpyrazine derivatives, carbazole derivatives, silole derivatives, spirocompounds, triphenylamine derivatives, naphthalimide derivatives, triphenylamine derivatives, pyrazoloquinoline derivatives, hydrazone derivatives, pyridine ring compounds, fluorene derivatives, benzoxazinone derivatives, phenanthroline derivatives, quinazolinone derivatives, quinophthalone derivatives, phenylene compounds, perinone derivatives, rubrene derivatives, styryl derivatives (distyrylbenzene derivatives, distyrylarylene derivatives, stilbene derivatives), thiophene derivatives (oligothiophene derivatives), dienes (cyclopentadiene derivatives, tetraphenyl butadiene derivatives), azole derivatives (oxadiazole derivatives, oxazole derivatives, triazole derivatives, benzoazatriazole derivatives), pyrazole derivatives (pyrazoline derivatives), and pyrrole derivatives (porphyrin derivatives, phthalocyanine derivatives).

The complex phosphors are not particularly limited, and are molecular compounds in which, according to the common definition, at least one ligand is coordinated to at least one central metal atom by coordinate bonding or hydrogen bonding, and in which the central metal atom is the emission center. Whether or not the central metal atom is an ion is not of concern. Examples of the emission center central metal atom include transition metals such as Fe, Cu, Zn, Al, and Au. Lanthanoid elements such as Gd, Yb, Y, Eu, Tb, Yb, Nd, Er, Sm, Dy, and Ce are particularly preferred for their advantages including; a large difference between the wavelength of absorbed light and the wavelength of emitted light, a small drop in emission efficiency due to fluorescence, resorption, and high quantum efficiency.

### Barrier Layer

The barrier layer 106 functions as a diffusion inhibiting layer that inhibits diffusion of phosphors from the phosphor layer 105 to the UV absorber layer 107, and diffusion of the UV absorber from the UV absorber layer 107 (described later) to the phosphor layer 105. Preferred as the barrier layer 106 are materials that are highly transparent, and have a dense structure, and that do not easily pass other molecules. Specific examples of the barrier layer 106 include polymer films of materials such as PET and other polyester resins, cellulose acetate, epoxy resins, silicone resins, polycarbonate-based resins, acrylic resins, polyether sulfone, cycloolefins, triacetate, and nylon resins, and transparent inorganic compounds such as a glass substrate. The glass substrate may be a transparent thin film synthesized from alkoxysilanes such as tetraetnoxysilane. From the standpoint of improving barrier property, the barrier layer 106 is preferably, for example, a PET or a nylon film including a silica film formed by a vapor deposit ion method.

The barrier layer 106 may have a thickness of 1 μm to 300 μm, provided that the transmittance in the visible light region does not fall below 95%, though the thickness depends on the type of barrier layer 106. When, the transmittance in the visible light region is less than 95%, the quantity of light that reaches the photoelectric conversion devices decreases, and this becomes a cause of poor solar cell efficiency. When the thickness is less than 1 μm, the barrier layer 106 becomes weaker, and defects such as breakage and twisting tend to occur during the manufacturing process. A thickness thicker than 300 μm is not preferable because it lowers the light transmittance, and causes poor output.

From the standpoint of inhibiting diffusion of phosphors from the phosphor layer 105 to the UV absorber layer 107, and diffusion of the UV absorber from the UV absorber layer 107 to the phosphor layer 105, the barrier layer 106 has a softening temperature above the manufacturing process temperature of the solar cell. When the softening temperature is lower than the manufacturing process temperature of the solar cell, the barrier layer 106 softens during manufacture, and it becomes difficult to inhibit diffusion of the UV absorber from, the UV absorber layer 107, or diffusion of phosphors from the phosphor layer 105. The manufacturing process temperature is typically the higher of the softening temperature of the constituent transparent material of the phosphor layer 105, and the softening temperature of the constituent transparent material of the UV absorber layer 107. Specifically, the softening temperature of the barrier layer 106 is preferably higher than the higher of the softening temperature of the constituent transparent material of the phosphor layer 105, and the softening temperature of the constituent transparent material of the UV absorber layer 107. Accordingly, for example, when an ethylene-vinyl acetate copolymer is used as the transparent material of the phosphor layer 105 and the UV absorber layer 107, the specific softening temperature is preferably higher than 90° C., a temperature about the same as the softening temperature of the ethylene-vinyl acetate copolymer, though the softening temperature depends on the type of the transparent material used for the phosphor layer 105 and the UV absorber layer 107. For example, polyester resins such as PET, and high-density polyethylene may be; used as materials having such a softening temperature.

### UV Absorber Layer

The UV absorber layer 107 is configured from a transparent resin layer containing a UV absorber. The transparent resin is not limited, and may be, for example, polyvinyl chloride, polyvinylidene chloride, polyvinyl alcohol, polystyrene, a styrene-acrylonitrile copolymer, a styrene-butadiene-acrylonitrile copolymer, polyethylene, an ethylene-vinyl acetate copolymer, polypropylene, polymethyl methacrylate, a methacryl styrene polymer, cellulose acetate, a polycarbonate, a polyester, PET, trivinylidene fluoride, an epoxy resin, a silicone resin, polyethersulfone, a cycloolefin, or triacetate. These may be used alone or as a mixture of two or more.

The UV absorber layer 107 may have a thickness of 100 μm to 1,000 μm. When the thickness is less than 100 μm, it is not possible to absorb the UV light that passed through the phosphor without being absorbed, and the photoelectric conversion devices will be damaged. A thickness thicker than 1,000 μm is not preferable because it leads to increased absorption of light in the visible region by the transparent resin itself, and causes poor conversion efficiency in the photoelectric conversion devices. The composition and the type of the UV absorber contained in the transparent resin are not limited. However, the UV absorber may be one having a peak absorption wavelength of 300 nm to 400 nm. When the peak absorption wavelength is less than 300 nm, an unabsorbed portion of UV light through the phosphor cannot be sufficiently absorbed, and the UV damage to the photoelectric conversion devices will increase. A peak absorption wavelength of more than 400 nm also falls outside of the wavelength, region of W light that passes through the phosphor layer 105, and it becomes difficult to protect the photoelectric conversion devices from UV light. A UV absorber with such a peak absorption wavelength also absorbs the longer wavelength light emitted by the phosphor, and becomes an obstacle for improving output through wavelength conversion by the phosphor. For transparency, the UV absorber is preferably an organic UV absorber such as a triazine compound, a benzotriazole compound, and a benzophenone compound. These UV absorbers may be used alone or in a combination of two or more.

Examples of the triazine compound include 2,4-bis(2-hydroxy-4-butoxyphenyl)-6-(2,4-dibutoxyphenyl)-1,3,5-triazine, and 2-[2-hydroxy-4-(1-octyloxycarbonylethoxy)phenyl]-4,6-bis(4-phenylphenyl)-1,3,5-triazine. Examples of the benzotriazole compound include 2-(3,5-di-t-butyl-2-hydroxyphenyl)benzotriazole, 2-(2H-benzotriazol-2-yl)-4,6-bis(1-methyl-1-phenylethyl)phenol, 2-(2-hydroxy-5-t-butylphenyl)-2H-benzotriazole, 2-(5-methyl-2-hydroxyphenyl)benzotriazole, 2-(2H-benzotriazol-2-yl)-6-(1-methyl-1-phenylethyl)-4-(1,1,3,3-tetramethylbutyl)phenol, 2-(3,5-di-t-butyl-2-hydroxyphenyl)-5-chlorobenzotriazole, 2-(3,5-di-t-amyl-2-hydroxyphenyl)benzotriazole, 2-(3-t-butyl-5-methyl-2-hydroxyphenyl)-5-chlorobenzotriazole, 2-(5-di-t-octyl-2-hydroxyphenyl)benzotriazole, and 2-[3-(2H-benzotriazol-2-yl)-4-hydroxyphenyl]ethyl methacrylate. Examples of the benzophenone compound include 2,2′-dihydroxy-4-methoxybenzophenone, 2,4-dihydroxybenzophenone, 2-hydroxy-4-n-dodecyloxybenzophenone, 2-hydroxy-4-methoxybenzophenone, and 2-hydroxy-4-n-octoxybenzophenone.

The UV absorber may be added in an amount that makes the transmittance 5% or less between 300 nm and 400 nm for the three-layer structure of the phosphor-containing layer 105, the barrier layer 106, and the UV absorber layer 107. For example, in the case of a benzophenone UV absorber, the UV absorber may be added in an amount of 0.05 weight parts or more and 5 weight parts or less with respect to the transparent resin for the UV absorber, though the amount varies with the type of the UV absorber added, or the type or the content of the phosphor in the phosphor-containing layer.

### Three-Layer Structure

The second sealing material layer 109 disposed on the light incident side of the photoelectric conversion devices 101 in the solar cell module 100 of the embodiment of the present disclosure has a three-layer structure combining the phosphor-containing layer 105, the barrier layer 106, and the UV absorber layer 107 described above. The phosphor layer 105, the harrier layer 106, and the UV absorber layer 107 are disposed in this order from the sunlight incident side. The combined thickness may range from 201 μm, a total of the minimum thicknesses of the three layers, to 2,300 μm, a total of the maximum thicknesses of the three layers. The transmittance is preferably 90% or more in the visible region, and 5% or less in an. ultraviolet region of 300 nm to 400 nm. When the visible region transmittance is less than 90%, the quantity of light available; for the conversion by the photoelectric conversion devices 101 becomes smaller, and this leads to poor output. When the UV region transmittance Is more than 5%, the quantity of UV light that passes through the second sealing material layer 109 in the three-layer structure increases, and the photoelectric conversion devices will be damaged. This results in a shorter life. The refractive indices of the phosphor layer 105, the barrier layer 106, and the UV absorber layer 107 are not limited. However, from the standpoint of reducing light reflectance at the layer boundaries, it is preferable that the layers closer to the light incident side have the same or smaller refractive index than, the underlying layers. Specifically, it is preferable to satisfy the relationship n₁≦n₂≦n₃, where n₁ is the refractive index of the phosphor layer 105, n₂ is the refractive index of the barrier layer 106, and n₃ is the refractive index of: the UV absorber layer 107.

The solar cell module 100 of the embodiment having such a configuration includes at least the back sheet 103, the first sealing material layer 102, the photoelectric conversion devices 101, the electrodes 104 connected to the photoelectric conversion, devices 101, the second sealing material layer 109, and the protective glass 108. The second sealing material layer 109 has a three-layer structure in which the first layer 105 contacting the protective glass 108 is a phosphor-containing transparent material, the second layer 106 is a transparent material, and the third layer 107 contacting the photoelectric conversion devices 101 is a UV absorber-containing transparent material. With this configuration, the phosphor contained in the first layer 105 absorbs the ultraviolet light contained in sunlight, and produces light of longer wavelengths that can be used for photoelectric conversion. This improves the photoelectric conversion efficiency. The UV absorber contained in the third layer 107 absorbs the UV light that passed through the first layer 105 without being absorbed, and UV damage to the photoelectric conversion devices 101 can be reduced. The second layer 106 inhibits diffusion of phosphors from the first layer 105 to the third layer 107, and diffusion, of the UV absorber from the third layer 107 to the first layer 105. This improves the conversion efficiency, and the life of the solar cell module 100.

### Manufacturing Method

The solar cell module 100 of the embodiment of the present disclosure may be manufactured using, for example, the following processes.

The phosphor layer 105 is produced first. A phosphor is dissolved or dispersed by a known method of mixing and kneading phosphors in a hot molten transparent resin, and the kneaded resin is formed into a sheet shape by roll drawing or heat press to produce the phosphor layer 105. For example, 24.8 g of a zinc-based inorganic phosphor powder (ZnSiO₄:Mn) having an average grain size of 40 nm is added to 200 g of an ethylene-vinyl acetate copolymer, and the mixture is kneaded at 100 rpm for about 30 minutes in a planetary mixer that has been heated to 120° C. Thereafter, 30 g of the kneaded product is pressed with a heat press that has been heated to 120° C., after adjusting the gap with a 300-μm stainless steel spacer. This is followed by cooling to obtain the phosphor layer 105.

The UV absorber layer 107 is produced next. For example, a UV absorber is dissolved or dispersed by a known method of mixing and kneading a UV absorber in a hot molten transparent resin, and the kneaded resin, is formed into a sheet shape by roll drawing or heat press to produce the UV absorber layer 107. For example, 1 g of benzophenone UV absorber 2,4-dihydroxybenzophenone is added to 200 g of an ethylene-vinyl acetate copolymer, and mixed at 100 rpm for about 30 minutes in a planetary mixer that has been heated to 120° C. The mixture is then pressed with a heat press that has been heated to 120° C., after adjusting the gap with a 300-μm stainless steel spacer. This is followed by cooling to obtain the UV absorber layer 107.

Separately, the barrier layer 106 is prepared. When the barrier layer 106 has a form of a sheet, the phosphor layer 105 and the UV absorber layer 107 are subjected, to a lamination process, such as roil drawing or heat press, with the barrier layer 106 sandwiched in between. This forms the sealing material layer 109 of a three-layer structure. When the barrier layer 106 has a shape other than a sheet form, the barrier layer 106 may be processed into a form of a sheet using a known method of roll drawing or heat pressing the hot molten product, or heating the hot molten product under reduced pressure. For example, a known polyvinyl alcohol sheet is prepared as the barrier layer 106, and sandwiched between the phosphor layer 105 prepared from the ZnSiO₄:Mn-containing ethylene-vinyl acetate copolymer, and the UV absorber layer 107 prepared from the 2,4-dihydroxybenzophenone-containing ethylene-vinyl acetate copolymer. These layers are then sandwiched between a pair of glass plates, and heated at 85° C. for about 60 minutes under reduced pressure to produce the second sealing material layer 109 of a three-layer structure in which the layers are in contact with each other under the weight of the glass.

For improved adhesion between the layers, the rolling or heat press temperature is set to preferably about the same temperature as the softening point of the transparent resin constituting the phosphor layer 105 or the UV absorber layer 107. In the example above, the second sealing material layer 109 of a three-layer structure may be produced by applying heat under reduced pressure at 85° C., a temperature above the softening temperature, 84° C., of the ethylene-vinyl acetate copolymer.

With this manufacturing method, the lamination process by heat press or rolling ensures lamination of the second sealing material layer 109, and only laminates containing no bubbles can be selected as the second sealing material layer 109. In this way, a low yield due to entry of bubbles can be prevented in the process of laminating the second sealing material layer 109 to other members of the solar cell module 100.

### Solar Cell Module Manufacturing Method A

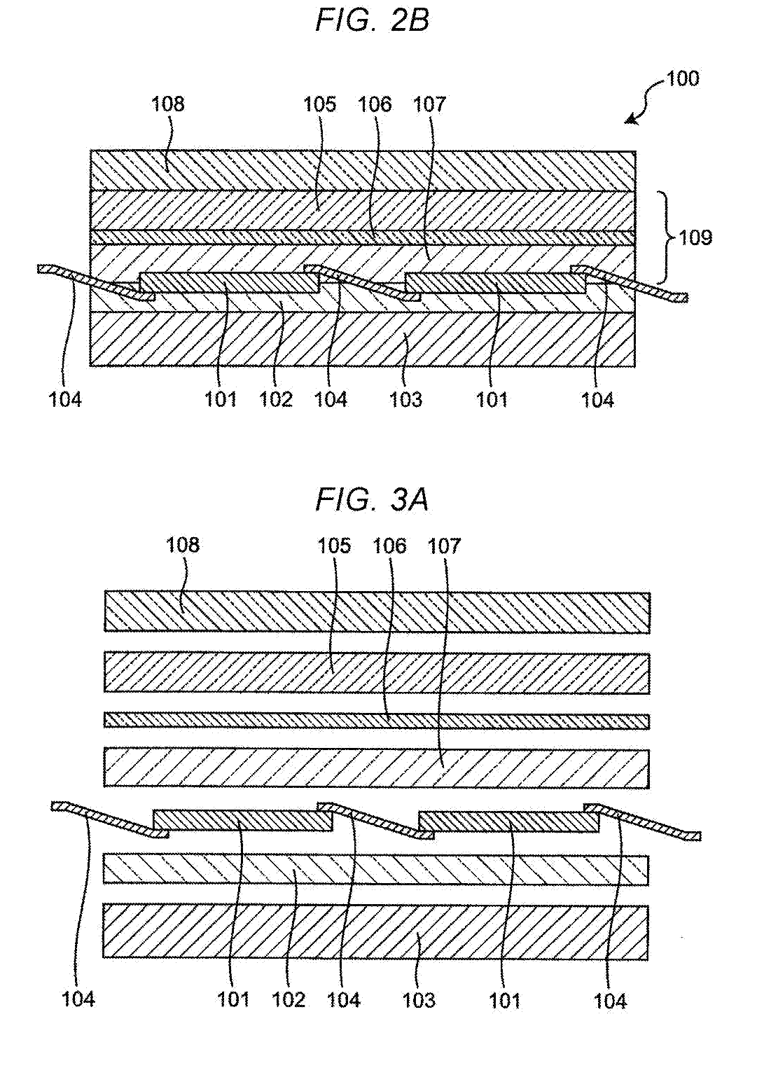

FIGS. 2A and 2B represent manufacturing method A as a method of laminating the second sealing material layer 109 to other members after producing the second sealing material layer 109 of the three-layer structure of the phosphor layer 105, the barrier layer 106, and the UV absorber layer 107. The lamination process involves stacking the back sheet 103, the first sealing material layer 102, the photoelectric conversion devices 101 electrically connected to one another by the electrodes 104, the second sealing material layer 109 of the three-layer structure disposed on the photoelectric conversion devices 101 on the UV absorber layer 107 side, and the protective glass 108, in this order, and laminating these members. The solar cell module 100 produced can have the following effects. Specifically, the phosphor in the phosphor layer 105 converts ultraviolet light into longer wavelength light to improve output, and the UV absorber in the UV absorber layer 107 absorbs the ultraviolet light that passed through the phosphor layer 105 without being absorbed so that the photoelectric conversion devices 101 are protected from UV damage. The barrier layer 106 inhibits diffusion of phosphors from the phosphor layer 105 to the UV absorber layer 107, and diffusion of the UV absorber from the UV absorber layer 107 to the phosphor layer 105. This improves output and life. Specifically, the solar cell module 100 of the embodiment can be produced as a solar cell module that uses a silver-plated copper wire as the electrodes 104, and a monocrystalline silicon photoelectric conversion, device as the photoelectric conversion devices 101, and in which the first sealing material layer 102 for the photoelectric conversion, devices 101 uses the same ethylene-vinyl acetate copolymer used for the phosphor layer and the UV absorber layer.

With this manufacturing method, the lamination process by heat press or rolling ensures lamination of the second sealing material layer, and only laminates containing no bubbles can be selected as the second sealing material layer 109. In this way, a low yield due to entry of bubbles can be prevented in the process of laminating the second sealing material layer 103 to other members of the solar cell module 100.

### Solar Cell Module Manufacturing Method B

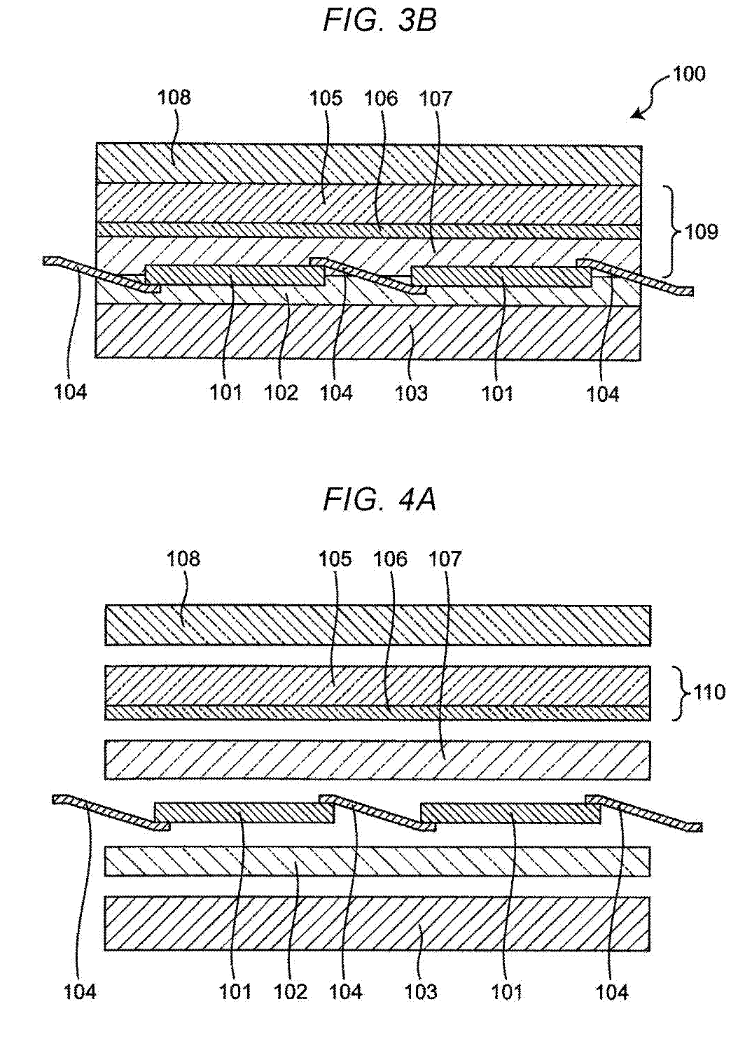

FIGS. 3A and 3B represent manufacturing method B as a method of laminating the phosphor layer 105, the barrier layer 106, and the UV absorber layer 107 with other members. The solar cell module 100 of the embodiment also can be produced by a lamination process that stacks the back sheet 103, the first sealing material layer 102, the photoelectric conversion devices 101 electrically connected to one another with the electrodes 104, the UV absorber layer 107, the barrier layer 106, the phosphor layer 105, and the protective glass 108, in this order, and that laminates these members, without producing the three-layer structure of the phosphor layer 105, the barrier layer 106, and the UV absorber layer 107 beforehand.

With this manufacturing method, the phosphor layer 105, the barrier layer 106, and the UV absorber layer 107 are laminated simultaneously with other members, without forming the three-layer structure in advance. This reduces the number of manufacturing steps, and improves productivity.

### Solar Cell Module Manufacturing Method C

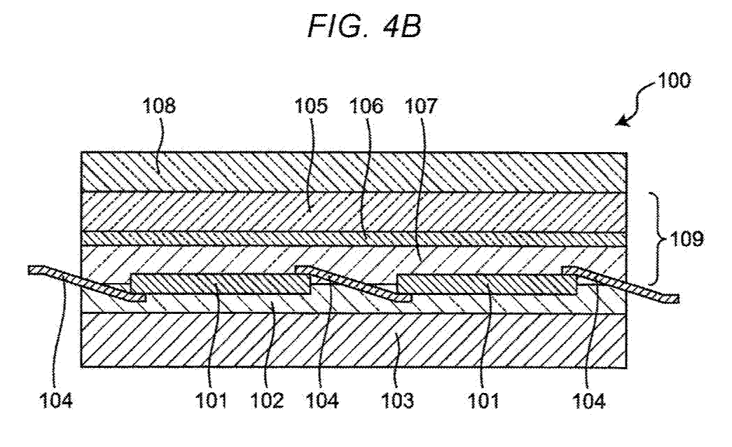

FIGS. 4A and 4B represent manufacturing method C as a method of directly applying a monomer solution, of a polymer to a surface of the phosphor layer 105 or to a surface of the UV absorber layer 107, and polymerizing the monomer to form the barrier layer 106, or as a method, of applying a hot molten transparent resin material, and cooling and solidifying the resin material to form the barrier layer 106. A monomer solution of a polymer is applied to a surface of the phosphor layer 105 or UV absorber layer 107 using a known method, for example, such as spin coating, and die coating, and cured by using a suitable method, such as heat curing, UV curing, and moisture curing. For example, a silicone resin monomer is applied to the phosphor layer 105 prepared from an ethylene-vinyl acetate copolymer containing an inorganic phosphor ZnSiO₄:Mn, using a die coating method, and heated at 60° C. for 4 hours to form a dimethylpolysiloxane film as the barrier layer 106. In this case, the phosphor layer 105 with the barrier layer 106, and the UV absorber layer 107 may be laminated to form the second sealing material layer 109 of a three-layer structure using a method such as roll drawing, heat press, or heating under reduced pressure, and the solar cell module 100 may be produced using the same process described in manufacturing method a represented in FIGS. 2A and 2B. The solar cell module 100 of the embodiment also may be produced by a lamination process in which a sealing material layer 110 of a bilayer structure including the barrier layer 106 formed therein is laminated to other members, as shown in FIGS. 4A and 4B. FIGS. 4A and 4B represent, an example in which the barrier layer 106 is formed beforehand on the phosphor layer 105. However, the same method can be used to manufacture the solar cell module 100 even when the barrier layer 106 is formed on the UV absorber layer 107.

With this manufacturing method, the barrier layer 106 is formed by applying a liquid material to the phosphor layer 105 or to the UV absorber layer 107, and the barrier layer 106 can more strongly adhere to the phosphor layer 105 or the UV absorber layer 107. This inhibits entry of bubbles or other unwanted substance, and improves productivity.

### Solar Cell Module Manufacturing Method D

The solar cell module 100 of the embodiment also may be manufactured by manufacturing method D, which is a method that first forms a sealing material layer of a bilayer structure by laminating the UV absorber layer 107 and the barrier layer 106, and then laminates the sealing material layer to the phosphor layer 105 and other members, or a method that forms a sealing material layer of a bilayer structure by laminating the phosphor layer 105 and the barrier layer 106, and laminates the sealing material layer to other members. The solar cell module 100 of the embodiment also can be manufactured according to the method represented in FIGS. 4A and 4B, using the sealing material layer of a bilayer structure.

With this manufacturing method, the lamination process by heat press or rolling ensures lamination of the phosphor layer 105 and the barrier layer 106, or lamination of the barrier layer 106 and the UV absorber layer 107, and only laminates containing no bubbles can be selected as the laminated layer. In this way, a low yield due to entry of bubbles can be prevented in the process of laminating the laminate to other members of the solar cell module 100.

Examples and Comparative Examples are described below in detail.

Tables 1 and 2 show the -compositions of the phosphor layer 105, the barrier layer 106, and the UV absorber layer 107, and the manufacturing methods used in Examples, and the compositions of the layers used in Comparative Examples, along with the evaluation results to be described later.

TABLE 1

| | | Ex. 1 | Ex. 2 |
|---|---|---|---|
| Phosphor | Phosphor | ZnSiO₄:Mn | ZnSiO₄:Mn |
| layer | Resin | EVA | EVA |
| | Content (weight part) | 12.4 | 12.4 |
| | Softening temperature of | 84 | 84 |
| | resin (° C.) | | |
| | Refractive index of resin | 1.49 | 1.49 |
| | Thickness (μm) | 300 | 300 |
| Barrier | Resin | PVA | Low-density |
| layer | | | polyethylene |
| | Refractive index | 1.49 | 1.54 |
| | Softening temperature of | 150 | 80 |
| | resin (° C.) | | |
| | Thickness (μm) | 50 | 50 |
| UV | UV absorber | 2,4-Dihydroxy- | 2,4-Dihydroxy- |
| absorber | | benzophenone | benzophenone |
| layer | Resin | EVA | High-density |
| | | | polyethylene |
| | Content (weight part) | 0.5 | 0.5 |
| | Softening temperature of | 84 | 120 |
| | resin (° C.) | | |
| | Refractive index of resin | 1.49 | 1.54 |
| | Thickness (μm) | 300 | 300 |
| Manufacturing method | | A | A |
| Transmittance at 350 nm (%) | | 2.1 | 1.6 |
| | | (Good) | (Good) |
| Output value relative to Comparative | | 0.6 | 0.3 |
| Example 1 at 100 | | (Excellent) | (Good) |
| Percentage of retained output value | | 99 | 97 |
| after 240 hours of continuous UV | | (Excellent) | (Good) |
| irradiation at 100 mW/cm² | | | |
| Overall Evaluation | | Excellent | Good |
| | | Ex. 3 | Ex. 4 |
| Phosphor | Phosphor | ZnSiO₄:Mn | ZnSiO₄:Mn |
| layer | Resin | EVA | EVA |
| | Content (weight part) | 19.7 | 12.4 |
| | Softening temperature of | 84 | 84 |
| | resin (° C.) | | |
| | Refractive index of resin | 1.49 | 1.49 |
| | Thickness (μm) | 300 | 300 |
| Barrier | Resin | Polystyrene | Silicone resin |
| layer | Refractive index | 1.59 | 1.43 |
| | Softening temperature of | 100 | 220 |
| | resin (° C.) | | |
| | Thickness (μm) | 50 | 50 |
| UV | UV absorber | 2,4-Dihydroxy- | 2,4-Dihydroxy- |
| absorber | | benzophenone | benzophenone |
| layer | Resin | EVA | EVA |
| | Content (weight part) | 0.5 | 0.5 |
| | Softening temperature of | 84 | 84 |
| | resin (° C.) | | |
| | Refractive index of resin | 1.49 | 1.49 |
| | Thickness (μm) | 300 | 300 |

| | | |
|---|---|---|
| Manufacturing method | A | B |
| Transmittance at 350 nm (%) | 1.1 | 2.1 |
| | (Excellent) | (Good) |
| Output value relative to Comparative | 0.2 | 98 |
| Example 1 at 100 | (Good) | (Excellent) |
| Percentage of retained output value | 98 | 98 |
| after 240 hours of continuous UV | (Good) | (Good) |
| irradiation at 100 mW/cm² | | |
| Overall Evaluation | Good | Good |

TABLE 2

| | | Ex. 5 | Ex. 6 |
|---|---|---|---|
| Phosphor | Phosphor | ZnSiO₄:Mn | ZnSiO₄:Mn |
| layer | Resin | EVA | EVA |
| | Content (weight part) | 12.4 | 12.4 |
| | Softening temperature of | 84 | 84 |
| | resin (° C.) | | |
| | Refractive index of resin | 1.49 | 1.49 |
| | Thickness (μm) | 300 | 300 |
| Barrier | Resin | Silicone resin | Silicone resin |
| layer | Refractive index | 1.43 | 1.43 |
| | Softening temperature of | 220 | 220 |
| | resin (° C.) | | |
| | Thickness (μm) | 50 | 50 |
| UV | UV absorber | 2,4-Dihydroxy- | 2,4-Dihydroxy- |
| absorber | | benzophenone | benzophenone |
| layer | Resin | EVA | EVA |
| | Content (weight part) | 0.5 | 0.5 |
| | Softening temperature of | 84 | 84 |
| | resin (° C.) | | |
| | Refractive index of resin | 1.49 | 1.49 |
| | Thickness (μm) | 300 | 300 |

| | | |
|---|---|---|
| Manufacturing method | C | D |
| Transmittance at 350 nm (%) | 2.1 | 2.1 |
| | (Good) | (Good) |
| Output value relative to Comparative | 0.5 | 0.6 |
| Example 1 at 100 | (Excellent) | (Excellent) |
| Percentage of retained output value | 98 | 98 |
| after 240 hours of continuous UV | (Good) | (Good) |
| irradiation at 100 mW/cm² | | |
| Overall Evaluation | Good | Good |

| | | Com. Ex. 1 | Com. Ex. 2 | Com. Ex. 3 |
|---|---|---|---|---|
| Phosphor | Phosphor | — | ZnSiO₄:Mn | ZnSiO₄:Mn |
| layer | Resin | — | EVA | EVA |
| | Content (weight part) | — | 12.4 | 12.4 |
| | Softening temperature of | — | 84 | 84 |
| | resin (° C.) | | | |
| | Refractive index of resin | — | 1.49 | 1.49 |
| | Thickness (μm) | — | 300 | 300 |
| Barrier | Resin | — | — | — |
| layer | Refractive index | — | — | — |
| | Softening temperature of | — | — | — |
| | resin (° C.) | | | |
| | Thickness (μm) | — | — | — |
| UV | UV absorber | 2,4-Dihydroxy- | 2,4-Dihydroxy- | — |
| absorber | | benzophenone | benzophenone | |
| layer | Resin | EVA | EVA | — |
| | Content (weight part) | 0.5 | 0.5 | — |
| | Softening temperature of | 84 | 84 | — |
| | resin (° C.) | | | |
| | Refractive index of resin | 1.49 | 1.49 | — |
| | Thickness (μm) | 300 | 300 | — |

| | | | |
|---|---|---|---|
| Manufacturing method | — | — | — |
| Transmittance at 350 nm (%) | 1.1 | 2.2 | 70 |
| | (Excellent) | (Good) | (Good) |
| Output value relative to Comparative | 0 | −1.3 | 0.9 |
| Example 1 at 100 | (Poor) | (Poor) | (Excellent) |
| Percentage of retained output value | 99 | 99 | 82 |
| after 240 hours of continuous UV | (Excellent) | (Excellent) | (Poor) |
| irradiation at 100 mW/cm² | | | |
| Overall Evaluation | Poor | Poor | Poor |

In Examples 1, 2, and 3, a second sealing material layer of a three-layer structure of the phosphor layer, the harrier layer, and the UV absorber layer was produced, and measured for transmittance at 350 nm. An evaluation module was produced by stacking the back sheet, the first sealing material layer, the photoelectric conversion devices connected to one another by electrodes, the sealing material layer of a three-layer structure, and the protective glass, in this order, and laminating these members. EVA is an abbreviation for ethylene-vinyl acetate copolymer.

In Example 4, a phosphor layer, a: silicone resin layer, and a UV absorber layer were prepared. The silicone resin layer was prepared as a sheet-like barrier layer of dimethylpolysiloxane. An evaluation module was produced, by stacking the back sheet, the first sealing material layer, the photoelectric conversion devices connected to one another by electrodes, the UV absorber layer, the barrier layer, the phosphor layer, and the protective glass, in this order, and laminating these members. Because a transmittance measurement at 350 nm was not possible, transmittance was measured for a separately prepared three-layer structure of the same phosphor layer, barrier layer, and UV absorber layer used to produce the evaluation module.

In Example 5, a sealing material layer of a bilayer structure was formed by applying a silicone resin monomer to the phosphor layer using a die coating method, and heating the monomer at 60° C. for 4 hours to form the barrier layer, specifically a sheet-like silicone resin layer of dimethylpolysiloxane. An evaluation module was produced by stacking the back sheet, the first sealing material layer, the photoelectric conversion devices connected to one another by electrodes, the UV absorber layer, the sealing material layer of a bilayer structure with the barrier layer facing the UV absorber layer, and the protective glass, in this order, and laminating these members. Because a transmittance measurement at 350 nm was not possible, the transmittance value measured for Example 4 of the same configuration was adopted.

In Example 6, a sealing material layer of a bilayer structure was formed by laminating the UV absorber layer to a dimethylpolysiloxane sheet, specifically a silicone resin layer. An evaluation module was produced by stacking the back sheet, the first sealing material layer, the photoelectric conversion devices connected to one another by electrodes, the sealing material layer of a bilayer structure with the UV absorber layer facing the photoelectric conversion devices, the phosphor layer, and the protective glass, in this order, and laminating these members. Because a transmittance measurement at 350 nm was not possible, the transmittance value measured for Example 4 of the same configuration, was adopted.

In Comparative Example 1, a UV absorber was produced, the transmittance at 350 nm was measured. An evaluation module was produced, by stacking the back sheet, the first sealing material layer, the photoelectric conversion devices connected to one another by electrodes, the UV absorber layer, and the protective glass, in this order, and laminating these members.

In Comparative Example 2, a sealing material layer having a bilayer structure of the phosphor layer and the UV absorber layer was produced by heat press, and measured for transmittance at 350 nm. An evaluation module was produced by stacking the back sheet, the first sealing material layer, the photoelectric conversion devices connected to one another by electrodes, the sealing material layer of a bilayer structure with the UV absorber layer facing the photoelectric conversion devices, and the protective glass, in this order, and laminating these members.

In Comparative Example 3, a phosphor layer was produced, and the transmittance at 350 nm was measured. An evaluation module was produced by stacking the back sheet, the first sealing material layer, the photoelectric conversion devices connected to one another by electrodes, the phosphor layer, and the protective glass, in this order, and laminating these members.

The evaluation modules were, measured for conversion efficiency. A rate of output change was also measured by applying ultraviolet light of 100 mW/cm² intensity for 240 hours using a UV irradiator.

These were evaluated under the following criteria.

### Transmittance

The film was measured for transmittance at 350 nm (350 nm (%)) with respect to the baseline measured for reference air.

### Evaluation Criteria

Transmittance of less than 1.5%: Excellent W blocking effect (Excellent)

Transmittance of 1.5% or more and less than 5%: Desirable UV blocking effect (Good)

Transmittance of 5% or more: Poor UV blocking effect (Poor)

### Output Value

The output of each module under the light of a Xe lamp was determined using a solar simulator, and a relative value with respect to the output value, 100, of Comparative Example 1 (a relative output value with respect to the output value of Comparative Example 1 taken as 100) was determined.

### Evaluation Criteria

Output value of 0.5 or more: Excellent output improvement (Excellent)

Output value of more than 0 and less than 0.5: Desirable output improvement (Good)

Output value of 0 or less: No output improvement (Poor) Percentage of Retained Output Value after Continuous UV Irradiation at 100 mW/cm² for 240 hours (%)

Ultraviolet light was continuously applied for 240 hours at 100 mW/cm². The ratio of the output value after irradiation with respect to the output value before irradiation was determined as a percentage of retained output.

### Evaluation Criteria

Percentage of 99% or more: Excellent reduction of UV damage (Excellent)

Percentage of 95% or more and less than 99%: Desirable reduction of UV damage (Good)

Percentage of less than 95%: Insufficient reduction of UV damage (Poor)

### Overall Evaluation

Examples and Comparative Examples that had at least one Poor score were determined as Poor, two or more Excellent scores with no Poor score were determined as Excellent in the overall evaluation of transmittance, output value, and percentage of retained output after UV irradiation. Examples and Comparative Examples that were neither Excellent nor Poor in the overall evaluation were determined as Good.

The following information can be derived from the results presented in Tables 1 and 2.

By comparing Example 1 and Example 3, it can be seen that the output decreases when the barrier layer has a higher refractive index than the UV absorber layer. By comparing Example 1 and Example 2, it can be seen that the output decreases when the barrier layer has a lower softening temperature than the phosphor layer or the UV absorber layer. By comparing Example 1 and Comparative Example 2, it can be seen that the output does not improve in the absence of the barrier layer. It can be seen from Examples 1, 4, 5, and 6 that the manufacturing methods A, B, C, and D are all effective. By comparing Example 1 and Comparative Example 1, it can be seen that the output value does not improve in the absence of the phosphor layer. By comparing Example 1 and Comparative Example 3, it can be seen that the percentage of retained output becomes smaller when the UV absorber layer is not provided.

In the embodiment described above, the second sealing material layer 109 provided on the protective glass 108 side of the photoelectric conversion devices 101 is a sealing material layer having a three-layer structure of the phosphor layer 105, the barrier layer 106, and the UV absorber layer 107. This inhibits diffusion of the UV absorber to the phosphor layer 105, and diffusion of phosphors to the UV absorber layer 107, and the high efficiency provided by wavelength conversion can remain for extended time periods in the solar cell module 100.

Any of the various embodiments or variations above may be appropriately combined such that an embodiment based on such a combination has the effects of different embodiments or variations. A combination of different embodiments or different Examples, and a combination of an embodiment and an Example may also be made. It is also possible to combine features of different embodiments or different Examples.

### INDUSTRIAL APPLICABILITY

As described above, the solar cell module, and the method of manufacture thereof according to the foregoing aspects of the present disclosure enable conversion of light into a form that can be effectively used by the photoelectric conversion devices, and inhibit UV damage to the photoelectric conversion devices. The solar cell module can thus have improved photoelectric conversion efficiency, and a longer life. This makes the disclosure highly useful for industry.

What is claimed is:

1. A, solar cell module comprising a back sheet, a first sealing material layer, a plurality of photoelectric conversion devices that are electrically connected to one another by an electrode material, a second sealing material layer, and a transparent protective material that are laminated in this order,
wherein the second sealing material layer is configured from a first layer, a second layer, and a third layer,
the first layer being disposed in contact with the transparent protective material and formed of a transparent material containing a phosphor,
the third layer being disposed in contact with the photoelectric conversion devices and formed of a transparent material containing an ultraviolet absorber,
the second layer being a transparent material disposed between the first layer and the third layer.

2. The solar cell module: according to claim 1, which satisfies the relationship n₁≦n₂≦b₃, where n₁ is a refractive index of the transparent material constituting the first layer, n₂ is a refractive index of the transparent material constituting the second layer, and n₃ is a refractive index of the transparent material constituting the third layer.

3. The solar cell module according to claim 1, wherein the transparent material constituting the second layer has a higher softening temperature than the transparent material constituting the first layer, and the transparent material constituting the third layer.

4. The solar cell module according to claim 1, wherein the transparent material constituting the first layer, and the transparent material constituting the third layer are an ethylene-vinyl acetate copolymer, or polyethylene.

5. A method for manufacturing the solar cell module of claim 1,
the method comprising:
forming the second sealing material layer of a three-layer structure in advance by laminating the first layer, the second layer, and the third layer;
electrically connecting the plurality of photoelectric conversion devices to one another with an electrode material;
stacking the back sheet, the first sealing material layer that fills between the back sheet and the photoelectric conversion devices, the plurality of photoelectric conversion devices that are electrically connected to one another with the electrode material, the second sealing material layer of the three-layer structure, and the transparent protective material in this order; and
laminating the stacked members.

6. A method for manufacturing the solar cell module of claim 1,
the method comprising:
electrically connecting the plurality of photoelectric conversion devices to one another with an electrode material;
stacking the back sheet, the first sealing material layer that fills between the back sheet and the photoelectric conversion devices, the plurality of photoelectric conversion devices electrically connected to one another with the electrode material, the third layer, the second layer, the first layer, and the transparent protective material in this order; and
laminating the stacked members.
